(19) United States
(12) Patent Application Publication
(10) Pub. No.: US 2012/0322187 A1
(43) Pub. Date: Dec. 20, 2012

(54) ETCHANTS AND METHODS OF FABRICATING METAL WIRING AND THIN FILM TRANSISTOR SUBSTRATE USING THE SAME

(75) Inventors: Jong-Hyun CHOUNG, Hwaseong-si (KR); Seon-il KIM, Seoul (KR); Ji-Young PARK, Hwaseong-si (KR); Jeanho SONG, Yongin-si (KR); Sanggab KIM, Seoul (KR); Shin Il CHOI, Hwaseong-si (KR); Youngchul PARK, Iksan-si (KR); Youngjun JIN, Iksan-si (KR); Suckjun LEE, Jeonju-si (KR); O byoung KWON, Wanju-gun (KR); Inho YU, Iksan-si (KR); Sanghoon JANG, Jeongu-si (KR); Minki LIM, Iksan-si (KR)

(73) Assignees: DONGWOO FINE-CHEM CO., LTD., Iksan-si (KR); SAMSUNG ELECTRONICS CO., LTD., Suwon-si (KR)

(21) Appl. No.: 13/366,696

(22) Filed: Feb. 6, 2012

(30) Foreign Application Priority Data
Jun. 14, 2011 (KR) 10-2011-0057644

(51) Int. Cl. H01L 33/08; H05K 13/00; C09K 13/08

(52) U.S. Cl. 438/34; 252/79.3; 216/13; 257/E33.053

(57) ABSTRACT

An etchant includes: a persulfate; a fluoride; an inorganic acid; a cyclic amine; a sulfonic acid; and one of an organic acid and a salt thereof.

This application claims priority to Korean Patent Application No. 10-2011-0057644, filed on Jun. 14, 2011, and all the benefits accruing therefrom under 35 U.S.C. §119, the entire contents of which are hereby incorporated by reference.

### BACKGROUND OF THE INVENTION

(1) Field of the Invention

The invention disclosed herein relates to an etchant and a method of fabricating a metal wiring and a thin film transistor substrate using the same.

(2) Description of the Related Art

A display device such as a liquid crystal display device, a plasma display device, an electrophoretic display device, and an organic electroluminescence device is extensively used.

The display device includes a substrate, and a plurality of pixels on the substrate. Each pixel includes a thin film transistor connected to a gate line and a data line on the substrate. In relation to the thin film transistor, a gate-on-voltage is inputted through the gate line and an image signal is inputted through the data line.

The gate line and the data line are formed of metal and patterned through a photolithography process.

### BRIEF SUMMARY OF THE INVENTION

The invention provides an etchant having a high etch rate and an improved aging property.

The invention also provides a method of fabricating a metal wiring with a reduced wiring defect such as disconnection between wirings.

The invention also provides a method of fabricating a thin film transistor substrate with a reduced manufacturing time and cost, and a reduced wiring defect such as wire disconnection.

Embodiments of the invention provide etchants including: a persulfate contained in an amount of about 0.5 weight % to about 20 weight %, with respect to a total weight of the etchant; a fluoride contained in an amount of about 0.01 weight % to about 2 weight %, with respect to the total weight of the etchant; an inorganic acid contained in an amount of about 1 weight % to about 10 weight %, with respect to the total weight of the etchant; a cyclic amine contained in an amount of about 0.5 weight % to about 5 weight %, with respect to the total weight of the etchant; a sulfonic acid contained in an amount of about 0.1 weight % to about 10.0 weight %, with respect to the total weight of the etchant; and at least one of an organic acid and a salt thereof contained in an amount of about 0.1 weight % to about 10 weight %, with respect to the total weight of the etchant.

The etchant may further include an amount of water such that the total weight of the etchant is 100 weight %.

The persulfate may be at least one of K₂S₂O₈, Na₂S₂O₈, or (NH₄)₂S₂O₈.

The fluoride may be at least one of an ammonium fluoride, a sodium fluoride, a potassium fluoride, an ammonium bifluoride, a sodium bifluoride, or a potassium bifluoride.

The inorganic acid may be at least one of a nitric acid, a sulfuric acid, a phosphoric acid, or a perchloric acid.

The cyclic amine may be at least one of aminotetrazole, imidazole, indole, purine, pyrazole, pyridine, pyrimidine, pyrrole, pyrrolidine, or pyrroline.

The sulfonic acid may be a p-toluene sulfonic acid or methane sulfonic acid.

The organic acid may be a carboxylic acid, a dicarboxylic acid, a tricarboxylic acid, or a tetracarboxylic acid.

The organic acid may be at least one of an acetic acid, a butanoic acid, a citric acid, a formic acid, a gluconic acid, a glycolic acid, a malonic acid, an oxalic acid, a pentanoic acid, a sulfobenzoic acid, a sulfosuccinic acid, a sulfophthalic acid, a salicylic acid, a sulfosalicilic acid, a benzoic acid, a lactic acid, a glyceric acid, a succinic acid, a malic acid, a tartaric acid, an isocitric acid, a propenoic acid, an imminodiacetic acid, or an ethylenediaminetetraacetic acid (“EDTA”).

The etchant may etch a multilayer including copper and titanium.

In other embodiments of the invention, methods of forming a metal wiring include: stacking a metal layer including copper and titanium; forming a photoresist layer pattern on the metal layer and etching a portion of the metal layer with the etchant by using the photoresist layer pattern as a mask; and removing the photoresist layer pattern.

In still other embodiments of the invention, methods of forming a thin film transistor substrate include: forming a gate line on a substrate, and a gate electrode connected to the gate line; forming a data line intersecting the gate line and insulated from the gate line, a source electrode connected to the data line, and a drain electrode spaced from the source electrode; and forming a pixel electrode connected to the drain electrode. The forming the gate line and the gate electrode may be the methods of forming a metal wiring described above.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain principles of the invention. In the drawings:

FIGS. 1A through 1E are cross-sectional views illustrating an exemplary embodiment of a method of forming a metal wiring with an etchant according to the invention.

FIG. 2 is a plan view illustrating an exemplary embodiment of a structure of a display device manufactured using the etchant according to the invention;

FIG. 3 is a cross-sectional view along line I-I′ of FIG. 2;

FIGS. 4A to 4C are sectional plan views sequentially illustrating an exemplary embodiment of manufacturing processes of a thin film transistor substrate in relation to a method of manufacturing a display device according to the invention;

FIGS. 5A to 5C are cross-sectional views taken along line II-II′ of FIGS. 4A to 4C, respectively;

FIGS. 6A and 6B are sectional scanning electron microscope (“SEM”) pictures before the photoresist layer of the metal wiring is removed using the first etchant;

FIGS. 7A and 7B are sectional SEM pictures after the photoresist layer of the metal wiring is removed using the second etchant; and

FIGS. 8A and 8B are sectional SEM pictures after the photoresist layer of the metal wiring is removed using the second etchant.

### DETAILED DESCRIPTION OF THE INVENTION

The invention will be described below in more detail with reference to the accompanying drawings. The invention may, however, be embodied in different forms and should not be constructed as limited to the embodiments set forth herein. Rather, these embodiments are provided so that this disclosure will be thorough and complete, and will fully convey the scope of the invention to those skilled in the art.

Hereinafter, exemplary embodiments of an etchant will be described according to the invention.

According to an exemplary embodiment of the invention, an etchant is used for forming a metal layer by etching a double layer stacked on a substrate and including copper and titanium. In more detail, the etchant may be used to etch the double layer including a titanium layer and a copper layer.

According to an exemplary embodiment of the invention, an etchant includes at least one of a persulfate, a fluoride, an inorganic acid, a cyclic amine, a sulfonic acid, an organic acid, or a salt of the organic acid.

The persulfate is a main oxidizer and simultaneously etches a titanium layer and a copper layer. The persulfate is contained in the etchant in an amount of about 0.5 weight % to about 20 weight %, with respect to a total weight of the etchant. When a content of the persulfate is lower than about 0.5 weight %, an etch rate is reduced, so that a desired amount etching may not be obtained. When a content of the persulfate is higher than about 20 weight %, an etch rate is too high, so that it is difficult to control the degree of etching, resulting in the titanium layer and the copper layer being over-etched.

The persulfate may include at least one of K₂₅₂O₈, Na₂S₂O₈, or (NH₄)₂₅₂O₈.

The fluoride etches the titanium layer and also removes a residue caused by the etching the titanium layer. The fluoride is contained in the etchant in an amount of about 0.01 weight % to about 2.0 weight %, with respect to a total weight of the etchant. When a content of the fluoride is less than about 0.01 weight %, it is difficult to etch a desired amount of the titanium layer. When a content of the fluoride is higher than about 2.0 weight %, a residue occurs from titanium etching. Moreover, when a content of the fluoride is higher than about 2.0 weight %, titanium as well as a glass substrate therebelow may be etched.

The fluoride may include at least one of an ammonium fluoride, a sodium fluoride, a potassium fluoride, an ammonium bifluoride, a sodium bifluoride, or a potassium bifluoride. Additionally, the fluoride may include a mixture thereof.

The inorganic acid is a secondary oxidizer. According to a content of the inorganic acid in the etchant, an etch rate may be controlled. The inorganic acid may react to a copper ion in the etchant, thereby preventing the copper ion from increasing and the etch rate from decreasing. The inorganic acid is contained in the etchant in an amount of about 1 weight % to about 10 weight %, with respect to a total weight of the etchant. When a content of the inorganic acid is lower than about 1 weight %, an etch rate is reduced so that the etch rate may not be fast enough. When a content of the inorganic acid is higher than 10 weight %, a crack may occur in a photoresist layer used during etching of a metal layer or the photoresist layer may be peeled off. If the photoresist layer has cracks or is peeled off, the titanium layer or the copper layer below the photoresist layer may be over-etched.

The inorganic acid may include at least one of a nitric acid, a sulfuric acid, a phosphoric acid or a perchloric acid.

The cyclic amine is an anticorrosive agent. According to a content of the cyclic amine in the etchant, an etching rate of the copper layer may be controlled. The cyclic amine is contained in the etchant in an amount of about 0.5 weight % to about 5.0 weight %, with respect to a total weight of the etchant. When a content of the cyclic amine is less than about 0.5 weight %, an etch rate of the copper layer is increased so that there is a possible risk in over-etching. When a content of the cyclic amine is higher than about 5.0 weight %, an etch rate of the copper layer is decreased so that the desired degree of etching may not be obtained.

The cyclic amine may include at least one of aminotetrazole, imidazole, indole, purine, pyrazole, pyridine, pyrimidine, pyrrole or pyrrolidine, pyrroline.

The sulfonic acid is an additive for preventing aging. The sulfonic acid is dissociated into a sulfate ion (SO₄²⁻) in the etchant to delay a hydrolysis rate of the ammonium persulfate.

The sulfonic acid prevents the instability in the etch rates of copper and titanium when the number of stored substrates to be processed is increased.

The sulfonic acid is contained in the etchant in an amount of about 0.1 weight % to about 10.0 weight %, with respect to a total weight of the etchant. The sulfonic acid may include p-toluene sulfonic acid or methane sulfonic acid.

At least one of the organic acid and a salt of the organic acid is contained in the etchant in an amount of about 0.1 weight % to about 10 weight %, with respect to a total weight of the etchant. As a content of the organic acid is increased in the etchant, an etch rate is decreased. Especially, the organic acid salt may serve as a chelate to form a complex with the copper ion of the etchant, so that an etch rate of the copper is adjusted. Accordingly, adjusting of the etch rate may be possible by adjusting the contents of the organic acid and the organic acid salt in the etchant to be in a proper level.

When a content of at least one of the organic acid and the organic acid salt is less than about 0.1 weight %, it is difficult to adjust an etch rate of copper, so that over-etching may occur. When a content of at least one of the organic acid and the organic acid salt is higher than about 10 weight %, an etch rate of copper is reduced so that an etching time may be lengthened during manufacturing or forming processes. As a result of this, the number of substrates able to be processed in a given time may be reduced.

The organic acid may include at least one of a carboxylic acid, a dicarboxylic acid, or a tricarboxylic acid. In more detail, the organic acid may include an acetic acid, a butanoic acid, a citric acid, a formic acid, a gluconic acid, a glycolic acid, a malonic acid, an oxalic acid, a pentanoic acid, a sulfobenzoic acid, a sulfosuccinic acid, a sulfophthalic acid, a salicylic acid, a sulfosalicilic acid, a benzoic acid, a lactic acid, a glyceric acid, a succinic acid, a malic acid, a tartaric acid, an isocitric acid, a propenoic acid, an imminodiacetic acid or an ethylenediaminetetraacetic acid (“EDTA”).

The organic acid salt may include at least one of a potassium salt, sodium salt, or ammonium salt of the organic acid.

The etchant may further include an additional etching regulator, a surfactant, and a pH regulator, in addition to the above-mentioned components.

A water may be included to the etchant to allow a total weight of the etchant to be about 100 weight %. The water may be a deionized water.

The etchant may further include additional components so long as the additional components do not adversely affect the desirable properties of the etchant discussed herein.

The etchant may be used for processes to manufacture an electric device and, in more detail, may be used to etch a metal layer stacked on a substrate during manufacturing processes of the electric device. According to one embodiment of the invention, an etchant is especially used to form a gate wiring by etching a double layer of titanium and copper during manufacturing processes of a display device.

The etchant of the invention may have less aging than a typical etchant. In the case of the typical etchant, deposition reaction occurs in the etchant so that a concentration of an oxidizer is reduced in the etchant. Accordingly, etching characteristics of the etchant of the invention, for example, an etch rate, a taper angle, and a unilateral critical dimension (“CD”) loss may be uniformly maintained. The etchant of the invention is added to the sulfonic acid, as a material for alleviating the aging. Accordingly, the accumulative number of substrates to be processed with the etchant of the invention per predetermined hour may be increased and a uniform etching result may be obtained.

Especially, when the etchant is used to etch a metal wiring including a titanium layer and a copper layer, the metal wiring having a taper angle θ of about 25° to about 50° may be obtained. The taper angle will be described with a comparative example.

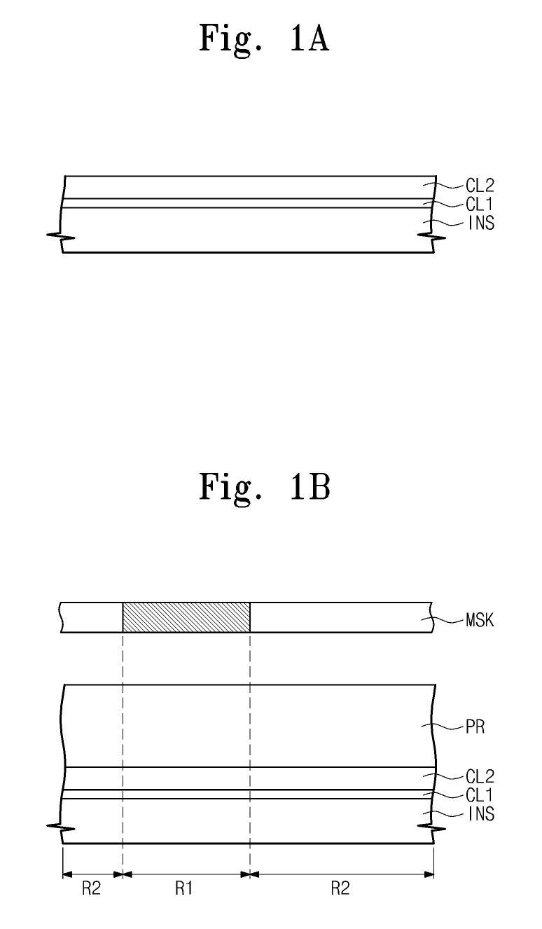

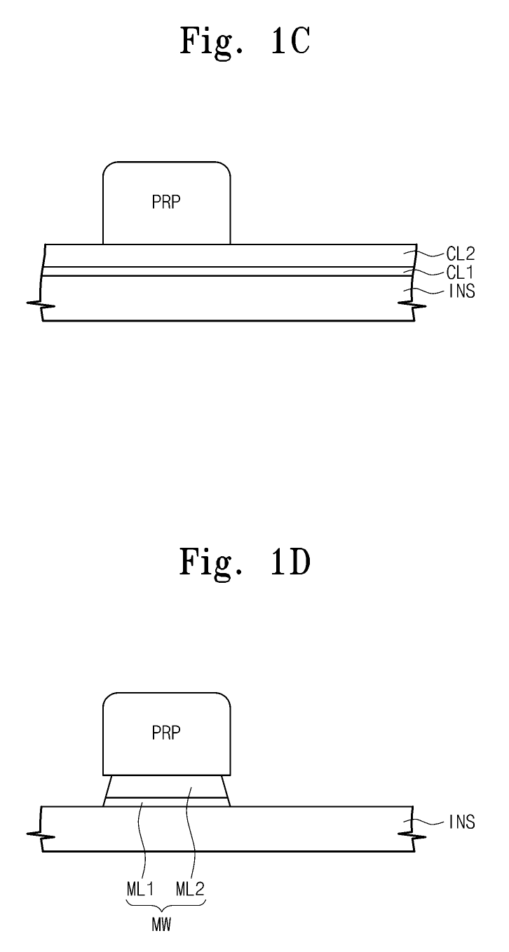

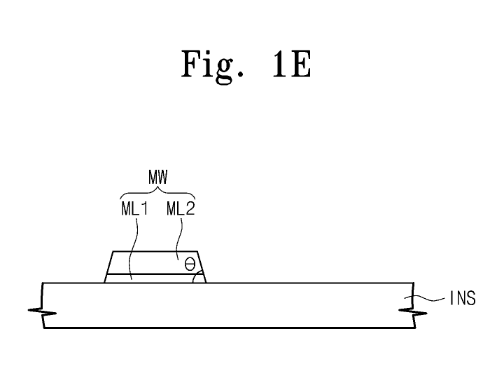

FIGS. 1A through 1E are cross-sectional views illustrating an exemplary embodiment of a method of forming a metal wiring with an etchant according to the invention.

Referring to FIG. 1A, a metal layer is stacked on an insulation substrate INS. The metal layer may be a double layer where a first metal layer CL1 formed of a first metal, and a second metal layer CL2 formed of a different second metal than the first metal, are sequentially stacked. Here, the first metal may be titanium and the second metal may be copper. Here, the metal layer is exemplarily a double layer but is not limited thereto. The metal layer may be a single layer formed of an alloy including the first metal and the second metal, or a multilayer formed of more than three layers where the first metal layer CL1 and the second metal layer CL2 are alternately stacked.

Next, as shown in FIG. 1B, after a photoresist layer PR is formed on the insulation substrate INS, the photoresist layer PR is exposed, for example, to light, through a mask MSK.

The mask MSK includes a first region R1 for screening or blocking all projected lights, and a second region R2 for transmitting some lights and screening other lights. An upper surface of the insulation substrate INS is divided into regions corresponding to the first region R1 and the second region R2. Hereinafter, the corresponding regions of the insulation substrate INS are referred as the first region R1 and the second region R2, respectively.

Next, after the photoresist layer PR exposed to light through the mask MSK is developed, as shown in FIG. 1C, only a photoresist layer pattern PRP of a predetermined thickness remains on a region where all lights are screened in the first region R1. The surface of the second metal layer CL2 in the second region R2 where all lights are transmitted is exposed because the photoresist layer PR is completely removed.

Here, according to the illustrated embodiment of the invention, a positive photoresist is used to remove a photoresist layer in the exposed region, but is not limited thereto. According to other embodiments of the invention, a negative photoresist may be used to remove a photoresist layer in the unexposed region.

Next, as shown in FIG. 1D, with the photoresist pattern PRP as a mask, the first metal layer CL1 and the second metal layer CL2 below and overlapping the photoresist pattern PRP are etched. During the etching of the first metal layer CL1 and the second metal layer CL2, the etchant according to the above-mentioned embodiment of the invention is used.

As a result, a metal wiring MW including a first metal wiring ML1 formed of the first metal and a second metal wiring ML2 formed of the second metal, is formed. Later, as shown in FIG. 1E, a final metal wiring MW is formed by removing the remaining photoresist pattern PRP.

After the above processes, a metal wiring having a taper angle θ and formed of the first metal and the second metal, e.g., a titanium/copper metal layer, is completely manufactured.

Since a display device is manufactured including the metal wiring fabricating method according to an embodiment of the invention, a structure of the display device is described first and then a method of manufacturing the display device is described with reference to the display device.

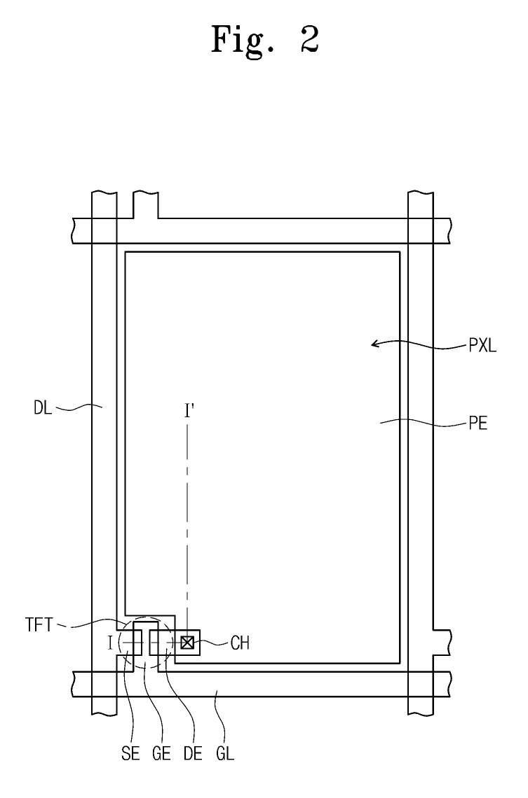

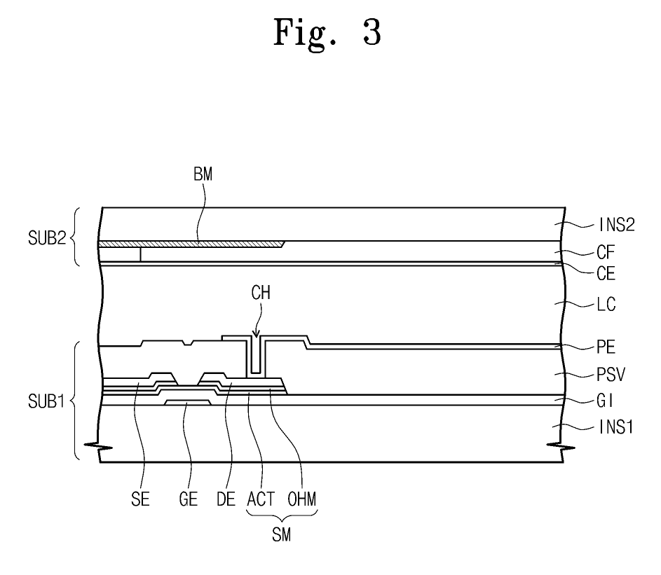

FIG. 2 is a plan view illustrating an exemplary embodiment of a structure of a display device manufactured using the etchant according to the invention. FIG. 3 is a cross-sectional view along line I-I′ of FIG. 2.

According to embodiments of the invention, the display device includes a plurality of pixels and displays an image. The display device is not specially limited and may include various display panels such as a liquid crystal display panel, an organic light emitting display panel, an electrophoretic display panel, an electrowetting display panel, and a micro electromechanical system display panel. According to an embodiment of the invention, the liquid crystal display device is shown as one example of the display panels. Here, each pixel has the same structure and thus, for convenience of description, an exemplary embodiment of one pixel is shown with the gate lines and the data lines adjacent to one of the pixels.

Referring to FIGS. 2 and 3, the display device includes a first substrate SUB1 having a plurality of pixels PXL, a second substrate SUB2 facing the first substrate SUB1, and a liquid crystal layer LC between the first substrate SUB1 and the second substrate SUB2.

The first substrate SUB1 includes a first insulation substrate INS1, and a plurality of gate lines GL and a plurality of data lines DL on the first insulation substrate INS1. The gate lines GL longitudinally extend in a first direction on the first insulation substrate INS1. The data lines DL are on a gate insulation layer GI and longitudinally extend in a second direction intersecting the first direction.

Each pixel PXL is connected to a corresponding one of the gate lines GL and a corresponding one of the data lines DL. Each pixel PXL includes a thin film transistor TFT and a pixel electrode PE connected to the thin film transistor TFT.

The thin film transistor TFT includes a gate electrode GE, a semiconductor layer SM, a source electrode SE, and a drain electrode DE.

The gate electrode GE protrudes from the gate line GL.

The semiconductor layer SM is provided on the gate electrode GE, with the gate insulation layer GI therebetween. The semiconductor layer SM includes an active layer ACT directly on the gate insulation layer GI, and an ohmic contact layer OHM directly on the active layer ACT. The active layer ACT is provided flat on a region having the source electrode SE and the drain electrode DE, and a region corresponding to a region between the source electrode SE and the drain electrode DE. The ohmic contact layer OHM is provided between the active layer ACT and the source electrode SE and between the active layer ACT and the drain electrode DE.

The source electrode SE is branched from the data line DL and, seen from the top in the plan view, at least a portion of the source electrode SE overlaps the gate electrode GE. The drain electrode DE is spaced from the source electrode SE and, seen from the top, at least a portion of the drain electrode DE overlaps the gate electrode GE.

The pixel electrode PE is physically and/or electrically connected to the drain electrode DE, with a passivation layer PSV therebetween. The passivation layer PSV has a contact hole CH which extends through a thickness thereof and exposes a portion of the drain electrode DE. The pixel electrode PE is connected to the drain electrode DE through the contact hole CH.

The second substrate SUB2 faces the first substrate SUB1 and includes a second insulation substrate INS2, a color filter CF on the second insulation substrate INS2 to represent color, a black matrix BM around an outer edge of the color filter CF to screen light, and a common electrode CE forming an electric field with the pixel electrode PE.

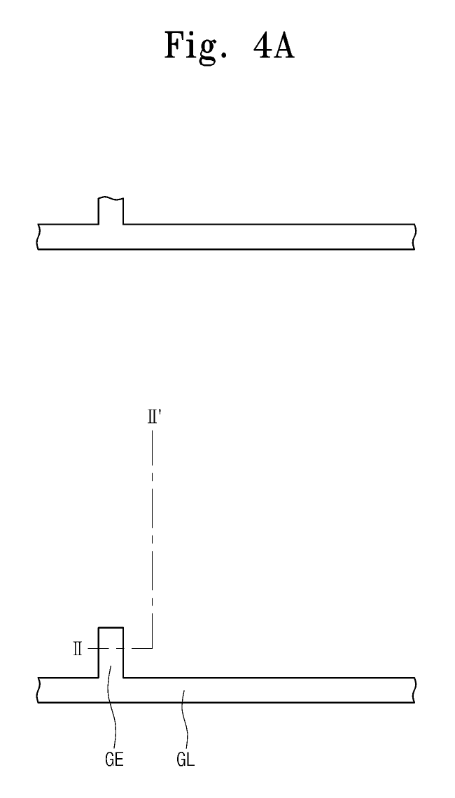

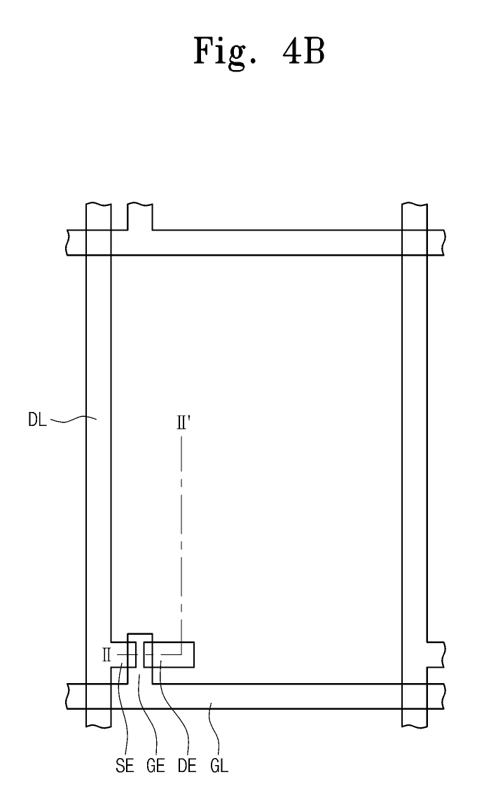

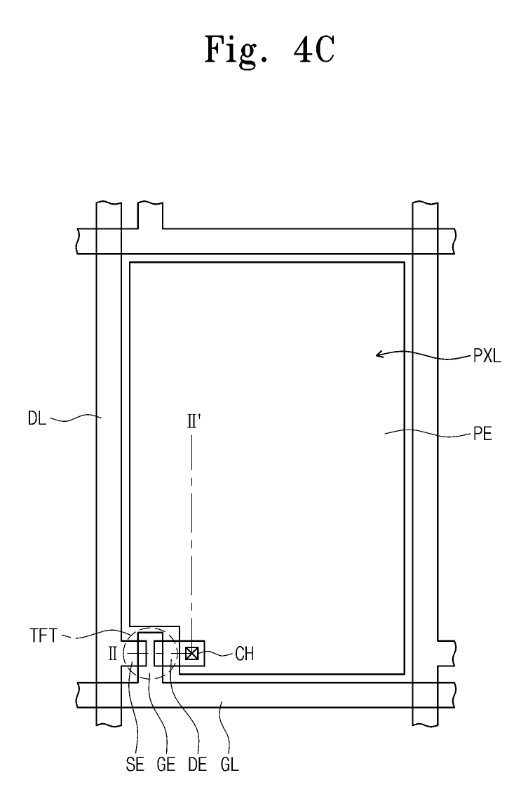

FIGS. 4A to 4C are sectional plan views sequentially illustrating an exemplary embodiment of manufacturing processes of a thin film transistor substrate in relation to a method of manufacturing a display device according to the invention.

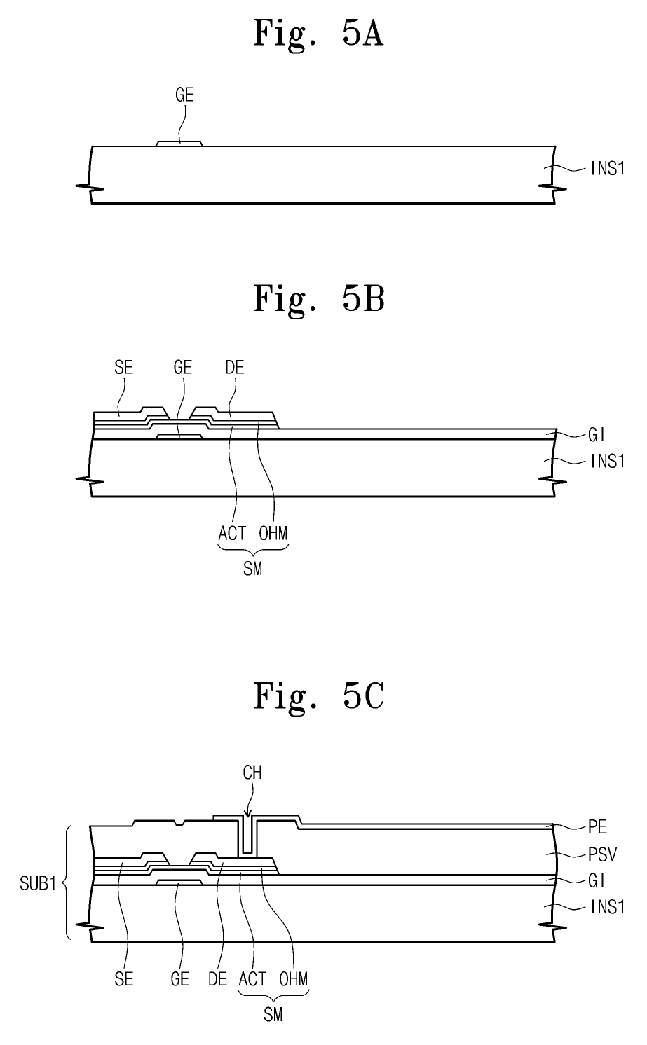

FIGS. 5A to 5D are cross-sectional views taken along line II-II′ of FIGS. 4A to 4C, respectively.

Hereinafter, an exemplary embodiment of a method of manufacturing a display device according to the invention will be described with reference to FIGS. 4A to 4C and 5A to 5C.

Referring to FIGS. 4A and 5A, a first wiring unit is formed on the first insulation substrate INS1 through a first photolithography process. The first wiring unit includes the gate line GL extending in a first direction, and the gate electrode GE connected to the gate line GL.

The gate line GL and the gate electrode are formed by sequentially stacking a first metal and a second metal on the first insulation substrate INS1 to form a first metal layer CL1, and a second metal layer CL2 on the first metal layer CL1 and then, etching the first metal layer CL1 and the second metal layer CL2 by using a first mask (not shown). The first metal layer CL1 may include titanium and the second metal layer may include copper. Here, the first metal layer CL1 may be formed with a thickness of about 50 angstroms (Å) to about 300 Å, and the second metal layer CL2 may be formed with a thickness of about 2000 Å to about 5000 Å. The first metal layer CL1 and the second metal layer CL2 are etched by the etchant according to the embodiment of the invention. At this point, the first wiring unit is etched to have a taper angle θ of about 25° to about 50°. The taper angle θ means an angle between a side of the metal wiring and an upper surface of the insulation substrate.

Accordingly, the gate line GL and the gate electrode GE are formed with a double layer structure where the first metal and the second metal are sequentially stacked.

Referring to FIGS. 4B and 5B, the gate insulation layer GI is formed on the first insulation substrate INS1 having the first wiring unit. A semiconductor layer SM and a second wiring unit are formed on the first insulation substrate INS1 having the gate insulation layer G1 through a second photolithography process. The second wiring unit includes the data line DL extending in a second direction intersecting the first direction, the source electrode SE extending from the data line DL, and the drain electrode DE spaced from the source electrode SE.

The gate insulation layer GI is formed by stacking a first insulation material on the first insulation substrate INS1 having the first wiring unit.

The second wiring unit is formed by sequentially stacking a first semiconductor material, a second semiconductor material, and a third conductive material on the first insulation substrate INS1 and selectively etching a first semiconductor layer (not shown), a second semiconductor layer (not shown), and a third conductive layer (not shown) formed of the first semiconductor material, the second semiconductor material, and the third conductive material, respectively, by using a second mask (not shown).

The second mask may be a slit mask or a diffraction mask.

The third conductive material is a metal such as copper, molybdenum, aluminum, tungsten, chrome, titanium, or an alloy thereof. When the third conductive layer is etched, a predetermined etchant proper to a metal used for the third conductive layer is used. The etchant may be different from the etchant used for forming the first wiring to allow a taper angle of the third conductive layer to be greater than that of the first wiring.

Referring to FIGS. 4C and 5C, the pixel electrode PE is formed on the first insulation substrate INS having the second wiring unit through third and fourth photolithography processes.

Referring to FIG. 5C, the passivation layer PSV having a contact hole CH that exposes a portion of the drain electrode DE is formed on the first insulation substrate INS1 having the second wiring unit. The passivation layer PSV is formed by stacking a second insulation material layer (not shown) and a photoresist layer (not shown) with a second insulation material on the first insulation substrate INS1 having the second wiring unit, forming a photoresist pattern (not shown) by exposing and developing the photoresist layer, and then removing a portion of the second insulation material layer by using the photoresist layer pattern as a mask.

Referring to FIG. 5C again, the pixel electrode PE disposed on the passivation layer PSV and connected to the drain electrode DE through the contact hole CH is formed through a fourth photolithography process. The pixel electrode PE is formed by sequentially stacking a transparent conductive material layer (not shown) and a photoresist layer (not shown) on the first insulation substrate INS1 having the passivation layer PSV, forming a photoresist layer pattern (not shown) by exposing and developing the photoresist layer, and then patterning the transparent conductive material layer by using the photoresist layer pattern as a mask.

The thin film transistor substrate manufactured through the above method, e.g., the first substrate SUB1, is bonded to the second substrate SUB2 having the color filter layer CF while facing the second substrate SUB2. The liquid crystal layer LC is formed between the first substrate SUB1 and the second substrate SUB2.

According to the illustrated embodiment, a thin film transistor substrate may be manufactured through a total of four photolithography processes. Here, by forming a metal wiring with an etchant according to the above-mentioned embodiment of the invention during a first photolithography process using the first mask, a gate electrode and a gate line having a proper taper angle may be completely formed and defective broken wires may be reduced or effectively prevented during forming of the first wiring unit.

Table 1 represents a result when a metal wiring is formed by etching a metal layer with an exemplary embodiment of an etchant according to the invention. The metal layer is formed by sequentially stacking titanium and copper. The metal wiring is fabricated by applying a photoresist layer on the metal layer, exposing and developing the photoresist layer, and then etching the metal layer with an exemplary embodiment of the etchant according to the invention.

TABLE 1

| | | Photoresist | Metal | | | Total |
|---|---|---|---|---|---|---|
| | | layer line | wiring | Uniformity | Unilateral | etching |
| Target line | Substrate | width | line | (relative | CD loss | time (s, |
| width (μm) | number | (μm) | width | value) | (μm) | at 30° C.) |
| 5.0 ± 1.5 | 1 | 7.20 | 5.15 | 12.2 | 2.05 | 71.0 |
| | 2 | 7.20 | 5.15 | 14.6 | 2.05 | 69.7 |
| | 3 | 7.20 | 4.52 | 13.3 | 2.68 | 82.2 |
| 6.0 ± 1.5 | 4 | 6.85 | 6.10 | 10.7 | 0.75 | 32.3 |
| | 5 | 6.85 | 5.92 | 10.5 | 0.93 | 38.0 |
| | 6 | 6.85 | 5.76 | 10.1 | 1.09 | 44.0 |

In Table 1, the target line width in micrometers (μm) represents a line width of a metal wiring to be formed. The photoresist layer line width in μm represents an actual line width of a photoresist layer after the photoresist layer is exposed and developed. The metal wiring line width represents an actual line width of a metal layer after the metal layer is etched by using the photoresist layer as a mask. The widths are taken perpendicular to a longitudinal direction of the metal wiring. The uniformity represents a uniformity of the metal wiring line width as a relative value. The total etching time is in seconds (s) at 30 degrees Celsius (° C.). Here, formation conditions of the metal layer, types of the photoresist layer, and exposure and development conditions are identically applied to the substrate numbers 1 to 6.

As shown in Table 1, when the metal layer is etched using the etchant of the invention, the actual width of the metal wiring is within tolerances of the target line width. That is, etching characteristics of the etchant of the invention used in a process of forming the metal wiring, for example, an etch rate, a taper angle, and a unilateral CD loss are uniformly maintained to successfully achieve the target dimension of the metal wiring.

Table 2 below illustrates a profile when a metal wiring is formed using a typical etchant and an exemplary embodiment of an etchant according to the invention. The metal layer is formed by stacking titanium and copper. The metal wiring is fabricated by applying a photoresist layer on the metal layer, exposing and developing the photoresist layer, and etching the metal layer with an etchant, specifically, the typical etchant and the exemplary embodiment of the etchant according to the invention, accordingly.

TABLE 2

| Item | Target range | | | First etchant | Second etchant |
|---|---|---|---|---|---|
| First temperature | 5 days, 5000 ppm | | | 3 days, 3000 ppm | 7 days, 7000 ppm |
| storage aging | | | | | |
| Second temperature | 10 days, 5000 ppm | | | 6 days, 3000 ppm | 10 days, 7000 ppm |
| storage aging | | | | | |
| The accumulated number | 600 sheets | | | 380 sheets | 870 sheets |
| of substrates to be | | | | | |
| processed (unit time) | | | | | |
| Time aging | Etching property change of less | | | Good for 12 hours | Good for 12 hours |
| | than about 10% for 12 hours | | | | |
| Etch rate | More than | 28° | C. | 100 Å/s | 153 Å/s |
| | about | 30° | C. | — | 172 Å/s |
| | 180 Å/s | 34° | C. | — | 200 Å/s |
| Unilateral CD loss | Cu 2000 Å | 0.5 | μm | 0.47 μm (50 s) | 0.48 μm (40 s) |
| (etching time) | Cu 5000 Å | 0.7 | μm | 0.81 μm (80 s) | 0.62 μm (60 s) |

| | | | | |
|---|---|---|---|---|
| Taper angle | Cu 2000 Å | 35° ± 10° | 34° | 34° |
| | Cu 5000 Å | 40° ± 10° | 31° | 30° |

In Table 2, the first etchant is a typical etchant and the second etchant is an exemplary embodiment of an etchant according to the invention. The first etchant includes ammonium persulfate, an inorganic acid, and an acetate as main components and is a product TCE-J00 of Dongjin Semichem Co., Ltd.

In Table 2, a first temperature and a second temperature of the first temperature storage aging and the second temperature storage aging are predetermined temperatures at which storage aging properties of the first etchant and the second etchant are defined. The second temperature is lower than the first temperature. The first and second storage aging are defined by days and concentration in parts per million (ppm). The time aging represents an etching property change of the etchant according to time. The etching property may mean an etch rate, a unilateral CD loss, and/or a taper angle. In Table 2, the unilateral CD loss and the taper angle were measured after a titanium layer was formed with a thickness of about 100 Å and copper layers were formed with respective thicknesses of about 2000 Å and about 5000 Å.

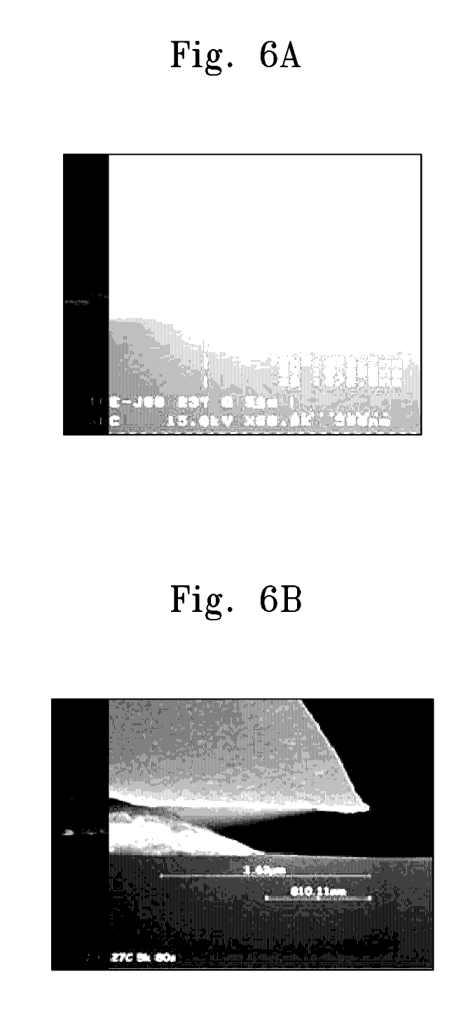

FIGS. 6A and 6B are sectional scanning electron microscope (“SEM”) pictures before the photoresist layer of the metal wiring is removed using the first etchant. FIG. 6A is a SEM picture showing a section of the metal wiring when the copper layer has a thickness of about 2000 Å. FIG. 6B is a SEM picture showing a section of the metal wiring when the copper layer has a thickness of about 5000 Å.

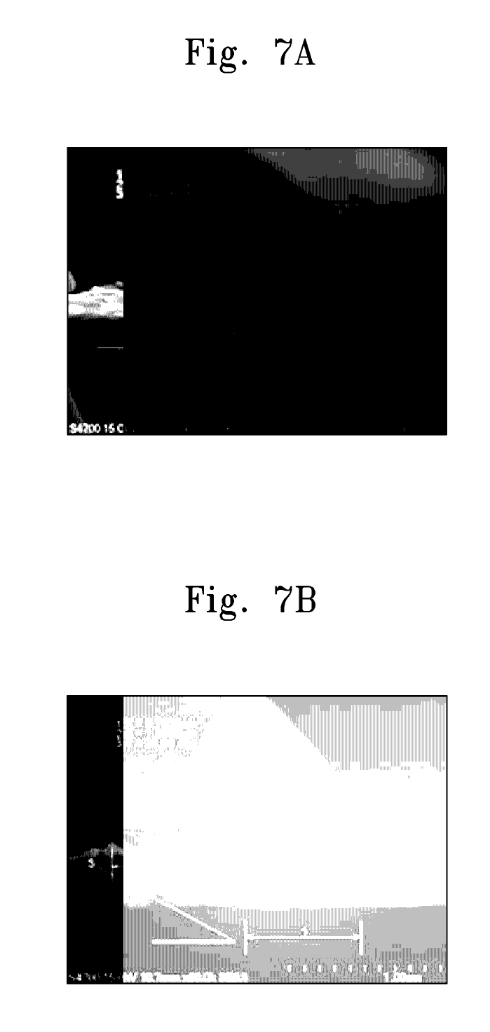

FIGS. 7A and 7B are sectional SEM pictures after the photoresist layer of the metal wiring is removed using the second etchant. FIG. 7A is a SEM picture showing a section of the metal wiring when the copper layer has a thickness of about 2000 Å. FIG. 7B is a SEM picture showing a section of the metal wiring when the copper layer has a thickness of about 5000 Å.

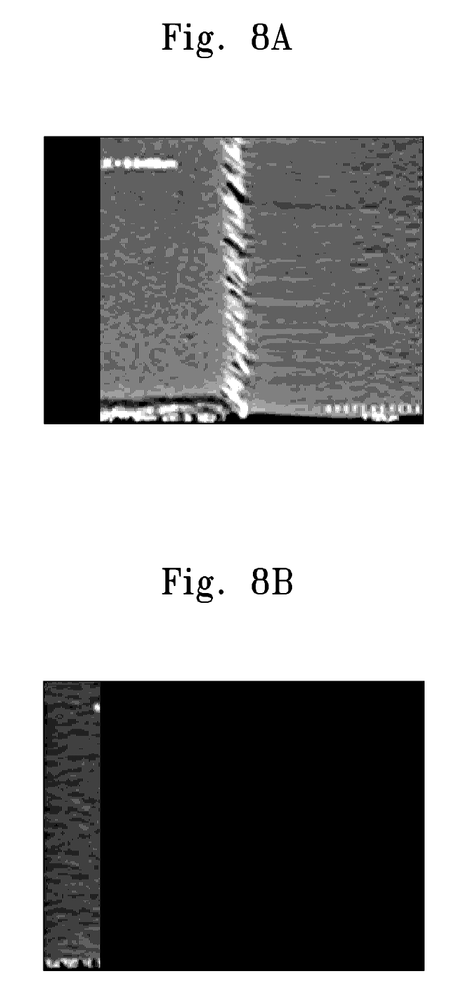

FIGS. 8A and 8B are sectional SEM pictures after the photoresist layer of the metal wiring is removed using the second etchant. FIG. 8A is a SEM picture showing a section of the metal wiring when the copper layer has a thickness of about 2000 Å. FIG. 8B is a SEM picture showing a section of the metal wiring when the copper layer has a thickness of about 5000 Å.

Referring to Table 2, when examining storage aging properties of the first etchant (e.g., the typical etchant) and the second etchant (e.g., the etchant of the invention), the first etchant had a concentration of less than a target range and thus had poor storage aging. However, the second etchant had a concentration satisfying a target range. This means that the storage aging of the second etchant was improved more than that of the first etchant.

While examining the actual accumulated number of substrates processed with the first etchant and the second etchant, when etching was performed with the first and second etchants, the number of substrates processed in a single time was 380 sheets and 870 sheets, respectively. That was, the number of substrates processed when the metal layer was etched using the second etchant is two times the number of substrates processed when the metal layer was etched using the first etchant. When the first etchant was used, the target number of substrates to be processed was not obtained but, when the second etchant was used, the target number of substrates to be processed was satisfied.

While examining time aging of the first etchant and the second etchant, etching properties of the first and second etchants were both maintained for more than about 12 hours.

While examining etch rates of the first etchant and the second etchant, an etch rate of the first etchant was lower than that of the second etchant. Additionally, when the first etchant was used for etching, a target etch rate was not obtained. However, when the second etchant was used for etching, a target etch rate was closely obtained at an etching temperature of about 30° C. and the target etch rate was obtained at an etching temperature of about 34° C.

When examining unilateral CD loss of the first and second etchants, when the first etchant was used for etching, an actual unilateral CD loss value was less than a target unilateral CD loss when a copper layer has a thickness of about 2000 Å. However, when the copper layer had a thickness of about 5000 Å, the actual unilateral CD loss value was more than the target unilateral CD loss. Compared to this, when the second etchant was used for etching, actual unilateral CD loss of the copper layers having thicknesses of about 2000 Å and about 5000 Å had values less than the target unilateral CD loss value.

When examining taper angles of the first etchant and the second etchant, both the first and second etchants had taper angles within the target range. The target range of the taper angle is between about 25° to about 50°. Here, a taper angle of less than about 25° means that the width of the metal wiring is narrow. If the width is less than a predetermined value, another metal wiring may be too thinly stacked on the metal wiring or wires may be disconnected. Or, a taper angle of more than about 50° causes a large step difference between the metal wiring and the substrate and also defects due to the step difference may occur. A typical defect due to the step difference is a roving of an alignment layer, and light leakage may occur due to the roving in an image of a final liquid crystal display device.

As mentioned above, exemplary embodiments of the invention provide an etchant having a high etch rate and improved aging, resulting in less gate disconnection defects and less gate pattern defects of a final wiring structure formed using the etchant.

According to an embodiment of the invention, provided is an etchant with a high etch rate and an improved aging property.

Additionally, according to an embodiment of the invention, provided is a metal wiring with reduced wiring defect such as wire disconnection.

Furthermore, according to an embodiment of the invention, provided are high quality display devices by fabricating a thin film transistor substrate through the metal wiring fabricating method.

The above-disclosed subject matter is to be considered illustrative, and not restrictive, and the appended claims are intended to cover all such modifications, enhancements, and other embodiments, which fall within the true spirit and scope of the invention. Thus, to the maximum extent allowed by law, the scope of the invention is to be determined by the broadest permissible interpretation of the following claims and their equivalents, and shall not be restricted or limited by the foregoing detailed description.

What is claimed is:

1. An etchant comprising:
a persulfate contained in an amount of about 0.5 weight % to about 20 weight %, with respect to a total weight of the etchant;
a fluoride contained in an amount of about 0.01 weight % to about 2 weight %, with respect to the total weight of the etchant;
an inorganic acid contained in an amount of about 1 weight % to about 10 weight %, with respect to the total weight of the etchant;
a cyclic amine contained in an amount of about 0.5 weight % to about 5 weight %, with respect to the total weight of the etchant;
a sulfonic acid contained in an amount of about 0.1 weight % to about 10.0 weight %, with respect to the total weight of the etchant; and
at least one of an organic acid or a salt thereof contained in an amount of about 0.1 weight % to about 10 weight %, with respect to the total weight of the etchant.

2. The etchant of claim 1, wherein the persulfate is at least one of K₂S₂O₈, Na₂S₂O₈, or (NH₄)₂S₂O₈.

3. The etchant of claim 2, wherein the fluoride is at least one of an ammonium fluoride, a sodium fluoride, a potassium fluoride, an ammonium bifluoride, a sodium bifluoride, or a potassium bifluoride.

4. The etchant of claim 2, wherein the inorganic acid is at least one of a nitric acid, a sulfuric acid, a phosphoric acid, or a perchloric acid.

5. The etchant of claim 2, wherein the cyclic amine is at least one of aminotetrazole, imidazole, indole, purine, pyrazole, pyridine, pyrimidine, pyrrole, pyrrolidine, or pyrroline.

6. The etchant of claim 2, wherein the sulfonic acid is a p-toluene sulfonic acid or methane sulfonic acid.

7. The etchant of claim 2, wherein the organic acid is a carboxylic acid, a dicarboxylic acid, a tricarboxylic acid, or a tetracarboxylic acid.

8. The etchant of claim 7, wherein the organic acid is at least one of an acetic acid, a butanoic acid, a citric acid, a formic acid, a gluconic acid, a glycolic acid, a malonic acid, an oxalic acid, a pentanoic acid, a sulfobenzoic acid, a sulfosuccinic acid, a sulfophthalic acid, a salicylic acid, a sulfosalicilic acid, a benzoic acid, a lactic acid, a glyceric acid, a succinic acid, a malic acid, a tartaric acid, an isocitric acid, a propenoic acid, an imminodiacetic acid, or an ethylenediaminetetraacetic acid.

9. The etchant of claim 1, further comprising an amount of water such that the total weight of the etchant is 100 weight %.

10. The etchant of claim 1, wherein the etchant etches a multilayer including of copper and titanium.

11. A method of forming a metal wiring, the method comprising:
forming a metal layer comprising copper and titanium;
forming a photoresist layer pattern on the metal layer;
etching a portion of the metal layer with an etchant by using the photoresist layer pattern as a mask; and
removing the photoresist layer pattern,
wherein the etchant comprises:
a persulfate contained in an amount of about 0.5 weight % to about 20 weight %, with respect to a total weight of the etchant;
a fluoride contained in an amount of about 0.01 weight % to about 2 weight %, with respect to the total weight of the etchant;
an inorganic acid contained in an amount of about 1 weight % to about 10 weight %, with respect to the total weight of the etchant;
a cyclic amine contained in an amount of about 0.5 weight % to about 5 weight %, with respect to the total weight of the etchant;
a sulfonic acid contained in an amount of about 0.1 weight % to about 10.0 weight %, with respect to the total weight of the etchant; and
at least one of an organic acid or a salt thereof of about 0.1 weight % to about 10 weight %, with respect to the total weight of the etchant.

12. The method of claim 11, wherein the metal layer comprises a first metal layer including the titanium, and a second metal layer including the copper on the first metal layer.

13. The method of claim 11, wherein the persulfate is at least one of K₂S₂O₈, Na₂S₂O₈, or (NH₄)₂S₂O₈.

14. The method of claim 13, wherein the fluoride is at least one of an ammonium fluoride, a sodium fluoride, a potassium fluoride, an ammonium bifluoride, a sodium bifluoride, or a potassium bifluoride.

15. The method of claim 13, wherein the inorganic acid is at least one of a nitric acid, a sulfuric acid, a phosphoric acid, or a perchloric acid.

16. The method of claim 13, wherein the cyclic amine is at least one of aminotetrazole, imidazole, indole, purine, pyrazole, pyridine, pyrimidine, pyrrole, pyrrolidine, or pyrroline.

17. The method of claim 13, wherein the sulfonic acid is a p-toluene sulfonic acid or methane sulfonic acid.

18. The method of claim 13, wherein the organic acid is a carboxylic acid, a dicarboxylic acid, a tricarboxylic acid, or a tetracarboxylic acid.

19. The method of claim 18, wherein the organic acid is at least one of an acetic acid, a butanoic acid, a citric acid, a formic acid, a gluconic acid, a glycolic acid, a malonic acid, an oxalic acid, a pentanoic acid, a sulfobenzoic acid, a sulfosuccinic acid, a sulfophthalic acid, a salicylic acid, a sulfosalicilic acid, a benzoic acid, a lactic acid, a glyceric acid, a succinic acid, a malic acid, a tartaric acid, an isocitric acid, a propenoic acid, an imminodiacetic acid, or an ethylenediaminetetraacetic acid.

20. The method of claim 11, wherein the etchant further comprises an amount of water such that the total weight of the etchant is 100 weight %.

21. A method of forming a thin film transistor substrate, the method comprising:
forming a gate line on a substrate, and a gate electrode connected to the gate line;
forming a data line intersecting the gate line and insulated from the gate line, a source electrode connected to the data line, and a drain electrode spaced from the source electrode; and
forming a pixel electrode connected to the drain electrode,
wherein the forming the gate line, and the gate electrode connected to the gate line comprises:
forming a metal layer comprising copper and titanium;
forming a photoresist layer pattern on the metal layer;
etching a portion of the metal layer with an etchant by using the photoresist layer pattern as a mask; and
removing the photoresist layer pattern,
wherein the etchant comprises:
a persulfate contained in an amount of about 0.5 weight % to about 20 weight %, with respect to a total weight of the etchant;
a fluoride contained in an amount of about 0.01 weight % to about 2 weight %, with respect to the total weight of the etchant;
an inorganic acid contained in an amount of about 1 weight % to about 10 weight %, with respect to the total weight of the etchant;
a cyclic amine contained in an amount of about 0.5 weight % to about 5 weight %, with respect to the total weight of the etchant;
a sulfonic acid contained in an amount of about 0.1 weight % to about 10.0 weight %, with respect to the total weight of the etchant; and
at least one of an organic acid or a salt thereof of about 0.1 weight % to about 10 weight %, with respect to the total weight of the etchant.

22. The method of claim 21, wherein the metal layer comprises a first metal layer including the titanium, and a second metal layer including the copper on the first metal layer.

23. The method of claim 21, wherein the etchant further comprises an amount of water such that the total weight of the etchant is 100 weight %.
